(19) United States
(12) Patent Application Publication
(10) Pub. No.: US 2009/0078567 A1
(43) Pub. Date: Mar. 26, 2009

(54) Method of connecting electrodes and hydrogen generating apparatus using the same

(75) Inventors: Jae-Hyoung Gil, Seoul (KR); Jae-Hyuk Jang, Seongnam-si (KR); Bo-Sung Ku, Suwon-si (KR); Kyoung-Soo Chae, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,868

(22) Filed: Apr. 7, 2008

(30) Foreign Application Priority Data
Sep. 20, 2007 (KR) 10-2007-0095692

(51) Int. Cl. C25B 9/00; B05D 1/00; C23C 14/34

(52) U.S. Cl. 204/242; 427/58; 204/192.15

(57) ABSTRACT

A method of connecting electrodes in a hydrogen generating apparatus and a hydrogen generating apparatus using this method are disclosed. The method of connecting the electrodes of a hydrogen generating apparatus may include: depositing a first terminal layer onto one side of a first electrode, which is configured to generate electrons; attaching one side of a wire onto the first terminal layer; depositing a second terminal layer onto one side of a second electrode, which is configured to receive the electrons and generate hydrogen; and attaching the other side of the wire onto the second terminal layer. Using this method, the resistance between electrodes can be reduced to increase the flow rate of hydrogen, and the distance between the electrodes can be minimized to reduce the volume of the hydrogen generating apparatus.

### CROSS-REFERENCE TO RELATED APPLICATIONS

This application claims the benefit of Korean Patent Application No. 10-2007-0095692 filed with the Korean Intellectual Property Office on Sep. 20, 2007, the disclosure of which is incorporated herein by reference in its entirety.

### BACKGROUND

1. Technical Field

The present invention relates to a method of connecting the electrodes of a hydrogen generating apparatus and to a hydrogen generating apparatus using the same.

2. Description of the Related Art

A fuel cell is an apparatus that converts the chemical energies of fuel (hydrogen, LNG, LPG, etc.) and air directly into electricity and heat, by means of electrochemical reactions. In contrast to conventional power generation techniques, which employ the processes of burning fuel, generating vapor, driving turbines, and driving power generators, the utilization of fuel cells does not entail combustion processes or driving apparatus. As such, the fuel cell is a relatively new technology for generating power, which offers high efficiency and few environmental problems.

FIG. 1 is a diagram illustrating the operational principle of a typical fuel cell.

Referring to FIG. 1, a fuel cell 100 may include a fuel electrode 110 as an anode and an air electrode 130 as a cathode. The fuel electrode 110 receives molecular hydrogen (H₂), which is dissociated into hydrogen ions (H⁺) and electrons (e⁻). The hydrogen ions move past a membrane 120 towards the air electrode 130. This membrane 120 corresponds to an electrolyte layer. The electrons move through an external circuit 140 to generate an electric current. The hydrogen ions and the electrons combine with the oxygen in the air at the air electrode 130 to generate water. The following Reaction Scheme 1 represents the chemical reactions described above.

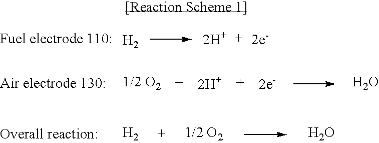

In short, the fuel cell can function as a battery, as the electrons dissociated from the fuel electrode 110 generate a current that passes through the external circuit. Such a fuel cell 100 is a pollution-free power source, because it does not produce any polluting emissions such as SOx, NOx, etc., and produces only little amounts of carbon dioxide. Also, the fuel cell may offer several other advantages, such as low noise and little vibration, etc.

One of the most crucial tasks required for the fuel cell is the stable supply of hydrogen. A hydrogen storage tank can be used for this purpose, but the tank apparatus occupies a large volume and has to be kept with special care.

In order for the fuel cell to suitably accommodate the demands in current portable electronic equipment (cell phones, laptops, etc.) for high-capacity power supply apparatus, the fuel cell needs to provide a small volume and high performance.

Thus, a reasonable alternative can be to produce hydrogen using a hydrogen generating apparatus. The hydrogen generating apparatus may convert a regular fuel containing hydrogen atoms into gases containing a large quantity of hydrogen gas, which can then be used by the fuel cell 100.

The fuel cell may employ a method of generating hydrogen after reforming fuel, such as methanol or formic acid, etc., approved by the ICAO (International Civil Aviation Organization) for boarding on airplanes, or may employ a method of using methanol, ethanol, or formic acid, etc., directly as the fuel.

However, the former case may require a high reforming temperature, a complicated system, and high driving power, and is likely to have impurities (e.g. CO₂, CO, etc.) included, besides pure hydrogen. On the other hand, the latter may entail the problem of very low power density, due to the low rate of a chemical reaction at the anode and the cross-over of hydrocarbons through the membrane.

In comparison, by using a hydrogen generating apparatus that utilizes electrochemical reactions, pure hydrogen can be obtained at room temperature. Also, a simple system can be implemented using only a cartridge and stack, and it is possible to obtain a desired flow rate of hydrogen without a separate BOP unit, by regulating the electric current to control the amount of hydrogen produced.

In the conventional hydrogen generating apparatus, a common method of connecting electrodes is to use clips. That is, clips may be secured to the wire to connect the electrodes with the control unit or connect the electrodes with each other. However, the contact resistance is high between an electrode and a clip, which leads to a low electric current, whereby the amount of hydrogen generated may be reduced.

### SUMMARY

An aspect of the invention is to provide a method of connecting electrodes in a hydrogen generating apparatus and a hydrogen generating apparatus using this method, with which the resistance between electrodes can be reduced to increase the flow rate of hydrogen, and in which the distance between the electrodes can be minimized to reduce the volume of the hydrogen generating apparatus.

One aspect of the invention provides a method of connecting electrodes of a hydrogen generating apparatus. The method includes: depositing a first terminal layer onto one side of a first electrode, which is configured to generate electrons; attaching one side of a wire onto the first terminal layer; depositing a second terminal layer onto one side of a second electrode, which is configured to receive the electrons and generate hydrogen; and attaching the other side of the wire onto the second terminal layer.

In certain embodiments, the operation of depositing the first terminal layer may be performed using a sputtering method. The first terminal layer can include a noble metal, such as gold (Au) and platinum (Pt), etc., and can be deposited to a thickness of 10 to 10,000 nm.

Before the operation of depositing the first terminal layer, a mask in which an aperture is formed that corresponds with the one side of the first electrode can be placed on the first electrode.

Also, before the operation of depositing the first terminal layer, a first attachment layer may be deposited onto the one side of the first electrode.

Here, the first attachment layer may contain such materials as titanium (Ti), chromium (Cr), nickel (Ni), and aluminum (Al), and may be deposited to a thickness of 1 to 1,000 nm.

Before the operation of depositing the second terminal layer, a mask in which an aperture is formed that corresponds with the one side of the second electrode can be placed on the second electrode.

Also, before the operation of depositing the second terminal layer, a second attachment layer may be deposited onto the one side of the second electrode.

In certain embodiments of the invention, attaching the wire can be performed by a soldering method.

Another aspect of the invention provides a hydrogen generating apparatus that includes: an electrolyte bath, which holds an aqueous electrolyte solution; a first electrode, which is held inside the electrolyte bath, configured to generate electrons, and has a first terminal layer formed on one side; a second electrode, which is held inside the electrolyte bath with a particular distance to the first electrode, configured to generate hydrogen using the electrons and the aqueous electrolyte solution, and which has a second terminal layer formed on one side; and a wire, one side of which is soldered to the first terminal layer, and the other side of which is soldered to the second terminal layer, to allow a movement of the electrons.

The hydrogen generating apparatus may additionally include a first attachment layer positioned between the first terminal layer and the first electrode.

Also, the hydrogen generating apparatus may include a second attachment layer positioned between the second terminal layer and the second electrode.

The first terminal layer can include a noble metal, such as gold (Au) and platinum (Pt), etc., and can be deposited to a thickness of 10 to 10,000 nm.

In addition, the first attachment layer may contain such materials as titanium (Ti), chromium (Cr), nickel (Ni), and aluminum (Al), and may be deposited to a thickness of 1 to 1,000 nm.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a diagram illustrating the operational principle of a typical fuel cell.

FIG. 2 is a schematic diagram illustrating a hydrogen generating apparatus.

FIG. 3 is a flowchart illustrating a method of fabricating an electrode according to an embodiment of the invention.

FIG. 4, FIG. 5, FIG. 6, FIG. 7, FIG. 8, and FIG. 9 are cross-sectional views illustrating a method of fabricating an electrode according to an embodiment of the invention.

FIG. 10 is a cross-sectional view of a hydrogen generating apparatus according to an embodiment of the invention.

FIG. 11 is a graph representing the flow rate of hydrogen generated using conventional electrodes.

FIG. 12 is a graph representing the flow rate of hydrogen generated by a hydrogen generating apparatus according to an embodiment of the invention.

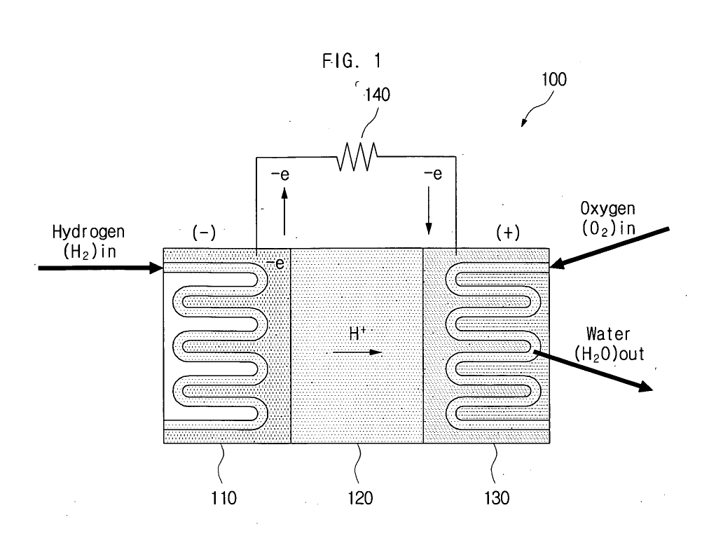

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Certain embodiments of the invention will now be described below in more detail with reference to the accompanying drawings.

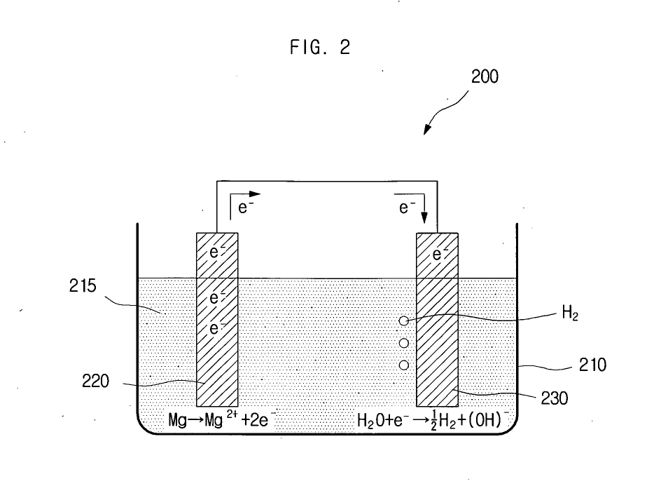

Methods used in generating hydrogen for a proton exchange membrane fuel cell (PEMFC) can be divided mainly into methods utilizing the oxidation of aluminum, methods utilizing the hydrolysis of metal borohydrides, and methods utilizing reactions on metal electrodes. Among these, one method of efficiently adjusting the rate of hydrogen generation is the method of using metal electrodes. FIG. 2 is a schematic diagram illustrating a hydrogen generating apparatus that uses metal electrodes.

In the illustrated drawing, an anode 220 made of magnesium and a cathode 230 made of stainless steel are dipped in an aqueous electrolyte solution 215 inside an electrolyte bath 210. The basic principle of the hydrogen generating apparatus 200 is that electrons are generated at the magnesium electrode 220, which has a greater tendency to ionize than the stainless steel electrode 230, and the generated electrons travel to the stainless steel 230 electrode. The electrons can then react with the aqueous electrolyte solution 215 to generate hydrogen.

The following Reaction Scheme 2 represents the chemical reactions in the hydrogen generating apparatus 200 described above.

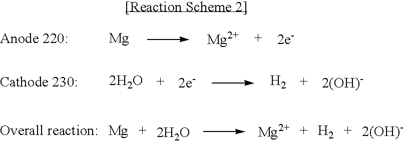

This is a method in which the electrons obtained when magnesium in the electrode 220 is ionized to Mg⁺ ions are moved through a wire and connected to another metal object (e.g. aluminum or stainless steel), where hydrogen is generated by the dissociation of water. The amount of hydrogen generated can be adjusted on demand, as it is related to the distance between electrodes and the sizes of the electrodes.

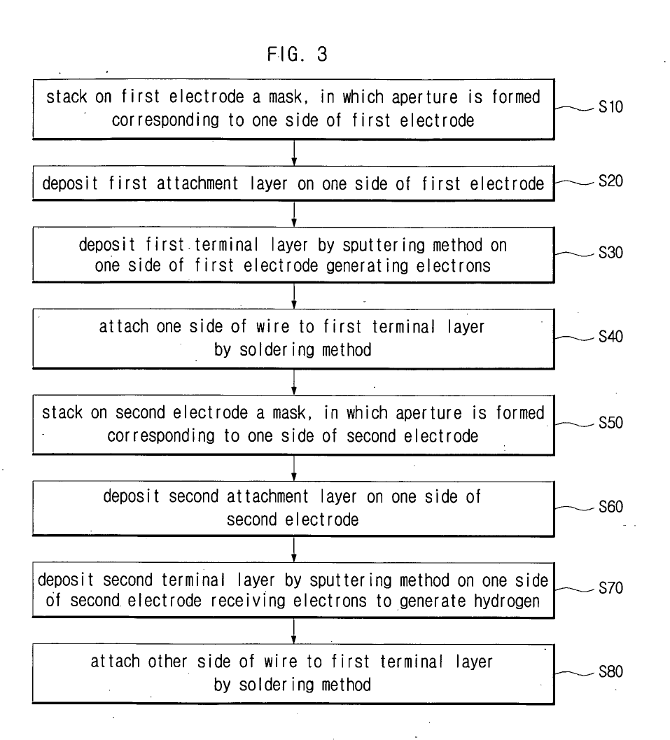

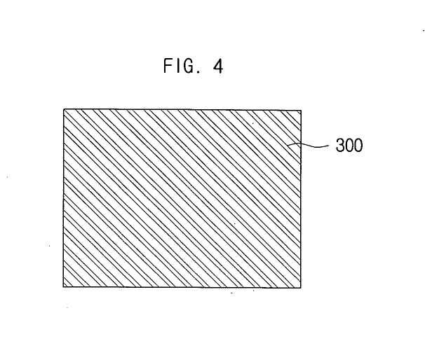

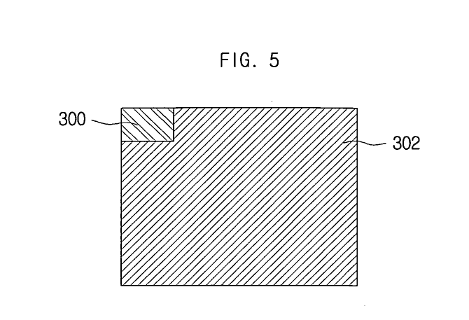

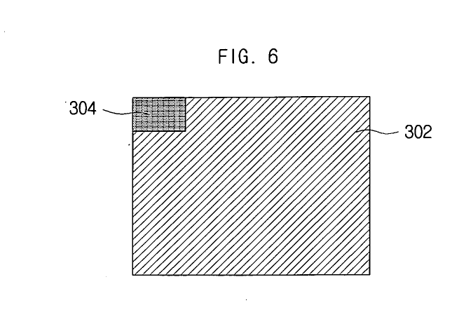

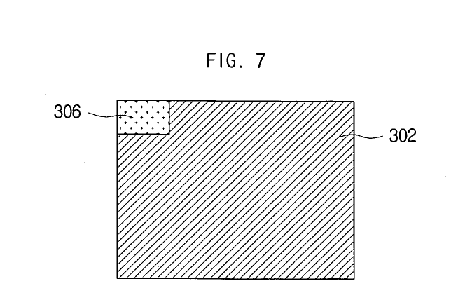

FIG. 3 is a flowchart illustrating a method of fabricating an electrode according to an embodiment of the invention, and FIG. 4 to FIG. 9 are cross-sectional views illustrating a method of fabricating an electrode according to an embodiment of the invention. In FIGS. 4 to 9 are illustrated a first electrode 300, a mask 302, a first terminal layer 306, and a first attachment layer 304.

In certain embodiments of the invention, the connections between electrodes can be implemented by depositing a thin-film terminal layer onto the electrode and attaching the wire by a soldering method, whereby the resistance between electrodes can be reduced, the flow rate of hydrogen can be increased, and the distance between electrodes can be minimized, to reduce the volume of the hydrogen generating apparatus.

For better understanding and easier explanations, the following description will focus on a configuration in which the first electrode 300 is made of magnesium (Mg) and the second electrode 400 is made of stainless steel.

The first metal electrode 300 is an active electrode, and due to the difference in ionization energy between the magnesium (Mg) electrode and water (H₂O), the magnesium electrode releases electrons (e⁻) into the water and becomes oxidized into magnesium ions (Mg²⁺).

In order to attach the wire to an electrode in an embodiment of the invention, first, as illustrated in FIG. 4, a first electrode 300 may first be prepared that will generate electrons, and then as illustrated in FIG. 5, a mask 302 having an aperture formed in correspondence with one side of the first electrode 300 that will generate electrons may be stacked on the first electrode 300 (S10). Here, the one side of the first electrode 300 refers to the region on which the first terminal layer 306 and the first attachment layer 304 are to be formed as described later. The region is not limited to any shape or size.

Next, as illustrated in FIG. 6, the first attachment layer 304 may be deposited on the one side where the first electrode 300 is exposed through the mask 302 (S20). The method of depositing may be performed by a sputtering method but is not thus limited, and it is obvious that other thin-film depositing methods may be used, such as evaporation and chemical vapor deposition (CVD).

The first attachment layer 304 can be made of any one of titanium (Ti), chromium (Cr), nickel (Ni), and aluminum (Al), but this embodiment will be described for an example that uses titanium. The first attachment layer 304 may be interposed between the first electrode 300 and the first terminal layer 306, which will be described later, to allow a better attachment between the first electrode 300 and the first terminal layer 306.

That is, a titanium layer 304 may be deposited as a thin film on a magnesium substrate 300 using a sputtering method. One reason for this is that it is difficult to deposit a gold thin film 306 directly on a magnesium substrate 300. Therefore, by interposing a titanium layer 304 between the magnesium substrate 300 and the gold thin film layer 306, the titanium layer 304 can be made to facilitate the attachment between the magnesium substrate 300 and the gold thin film layer 306.

Also, the first attachment layer 304 can be deposited to a thickness of 1 to 1,000 nm. If the first attachment layer 304 is deposited to a thickness less than 1 nm, the first electrode 300 and the first terminal layer 306 may not be adequately attached, whereas if the first attachment layer 304 is deposited to a thickness greater than 1,000 nm, there may be difficulties in implementing the first electrode 300 as a thin layer.

Next, as illustrated in FIG. 7, the first terminal layer 306 may be deposited onto the first attachment layer 304 of the first electrode 300 (S30). That is, a gold thin film layer 306 may be deposited onto the titanium layer 304. The gold thin film layer 306 allows a more effective soldering, when the wire 310 is soldered onto the magnesium substrate 300.

The first terminal layer 306 can be made of a noble metal, such as gold (Au), platinum (Pt), etc., and can be deposited to a thickness of 10 to 10,000 nm.

If the thickness of the first terminal layer 306 is less than 10 nm, it may be difficult to attach the wire, whereas if the thickness of the first terminal layer 306 is greater than 10,000 nm, there may be difficulties in implementing the first electrode 300 as a thin layer.

Next, as illustrated in FIG. 8, the mask 302 may be removed, and as illustrated in FIG. 9, one side of the wire 310 may be attached to the first terminal layer 306 by soldering to form a wire securing portion 308 (S40).

The method of securing the wire on the second electrode, which receives the electrons formed at the first electrode 300 to generate hydrogen, may be substantially the same as the method used for the first electrode 300.

Thus, a mask may be stacked on the second electrode that has an aperture formed in correspondence with one side of the second electrode (S50), and a second attachment layer may be deposited onto one side of the second terminal layer (S60). Here, the deposited second attachment layer can be a metal layer substantially the same as the first attachment layer 304 deposited on the first electrode 300 described above. Therefore, the second attachment layer deposited on the second electrode may be of substantially the same type and thickness as the first attachment layer 304 deposited on the first electrode 300.

Next, a second terminal layer may be deposited onto the second attachment layer of the second electrode (S70). Here, the second terminal layer can be a metal layer substantially the same as the first terminal layer 306 deposited on the first electrode 300, and thus may be of substantially the same type and thickness as the first terminal layer 306.

Finally, the other side of the wire may be attached to the second terminal layer by soldering (S80). The method of soldering the wire onto the second electrode may be substantially the same as the method used for the first electrode 300 described above.

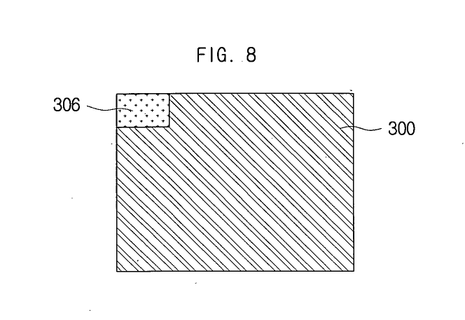

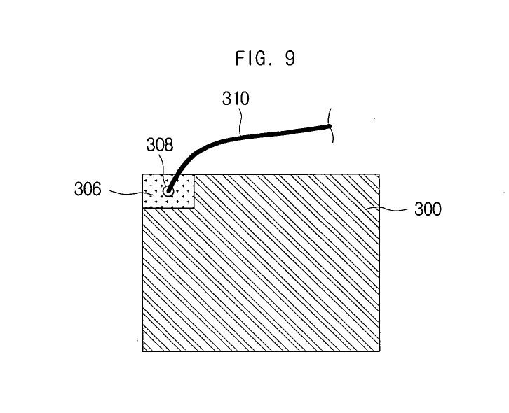

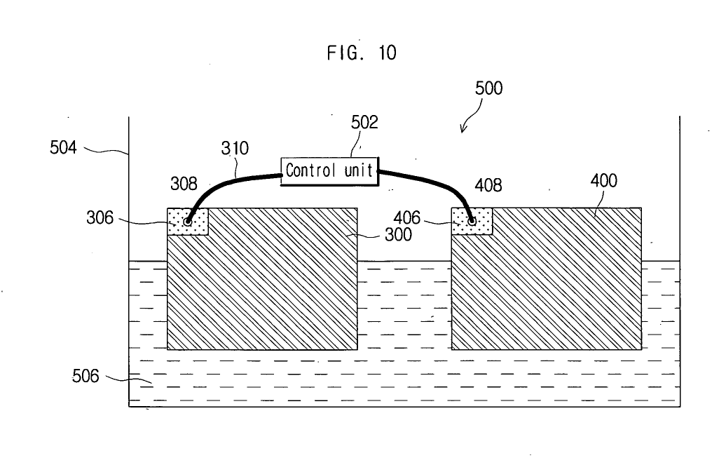

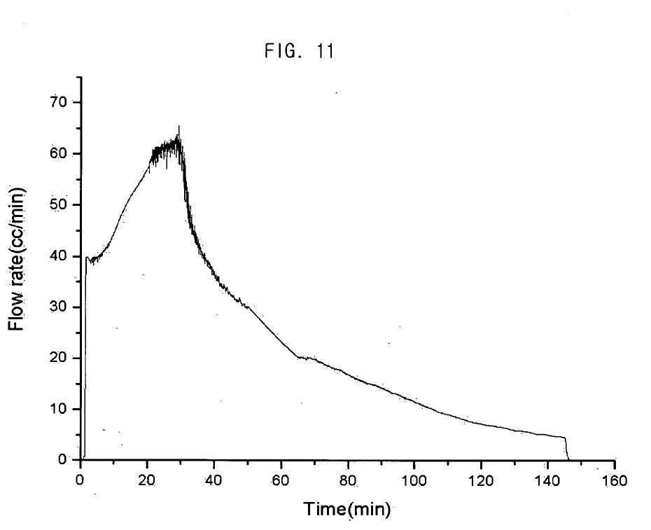

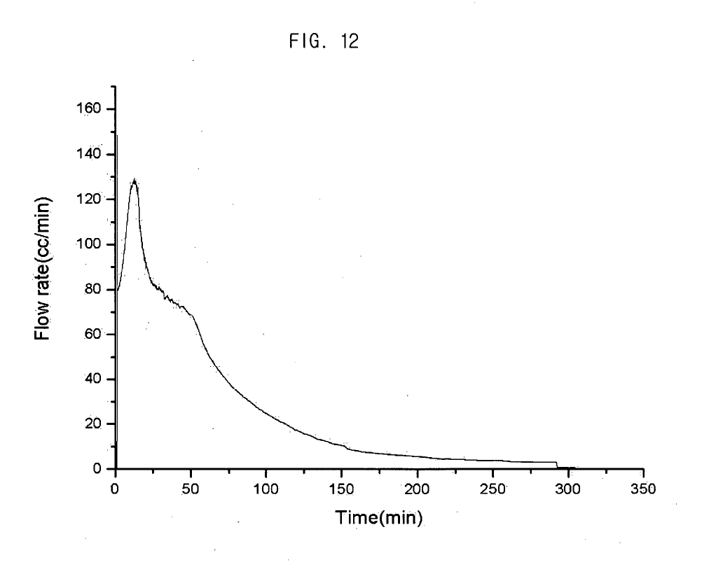

FIG. 10 is a cross-sectional view of a hydrogen generating apparatus according to an embodiment of the invention, FIG. 11 is a graph representing the flow rate of hydrogen generated using conventional electrodes, and FIG. 12 is a graph representing the flow rate of hydrogen generated by a hydrogen generating apparatus according to an embodiment of the invention.

In FIG. 10 are illustrated a first electrode 300, a first terminal layer 306, wire securing portions 308, 408, a wire 310, a second electrode 400, a second terminal layer 406, a hydrogen generating apparatus 500, a control unit 502, an electrolyte bath 504, and an aqueous electrolyte solution 506.

As illustrated in FIG. 10, the first terminal layer 306 and the second terminal layer 406 may be deposited as thin films on the first electrode 300, which generates electrons, and the second electrode 400, which receives the electrons to generate hydrogen. The wire 310 may be attached to each of the first terminal layer 306 and the second terminal layer 406 by soldering, such that the two electrodes are connected.

Of course, the first electrode 300 and second electrode 400 illustrated in FIG. 10 may be electrodes fabricated by the method of fabricating an electrode illustrated in FIGS. 4 to 9.

An aqueous electrolyte solution 506 may be contained inside the electrolyte bath 504. The aqueous electrolyte solution 506 may contain hydrogen ions, which can be used by the hydrogen generating apparatus 500 to generate hydrogen gas.

A compound such as LiCl, KCl, NaCl, KNO₃, NaNO₃, CaCl₂, MgCl₂, K₂SO₄, Na₂SO₄, MgSO₄, AgCl, etc., can be used in the aqueous electrolyte solution 506 as the electrolyte.

The first electrode 300 may be formed on one side within the electrolyte bath 504 and may generate electrons. The first electrode 300 may be an active electrode, where the magnesium (Mg) is oxidized into a magnesium ion (Mg²⁺) releasing two electrons, due to the difference in ionization energy between magnesium and water (H₂O). The electrons thus generated may travel through the wire 310 to the second electrode 400. As such, the first electrode 300 may be expended in accordance with the electrons generated, and may have to be replaced after a certain period of time. Also, the first electrode 300 may be made of a metal having a greater tendency to ionize than the material used for the second electrode 400.

The second electrode 400 may be formed adjacent to the first electrode 300, and may generate hydrogen using the electrons and the aqueous electrolyte solution 506. The second electrode 400 may be an inactive electrode. The second electrode 400 may receive the electrons that have traveled from the magnesium of the first metal electrode 300 and may react with the aqueous electrolyte solution 506 to generate hydrogen.

Also, as the second electrode 400 may be an inactive electrode and may not be expended, unlike the first electrode 300, the second electrode 400 may be formed to a lower thickness than that of the first electrode 300.

To be more specific, the chemical reaction at the second electrode 400 involves water being dissociated at the second electrode 400 after receiving the electrons from the first electrode 300. The reaction above can be represented by the following Reaction Scheme 3.

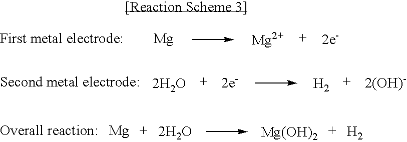

The rate and efficiency of the chemical reactions described above are determined by a number of factors. Examples of factors that determine the reaction rate include the area of the first electrode 300 and/or the second electrode 400, the concentration of the aqueous electrolyte solution 506, the type of aqueous electrolyte solution 506, the number of first electrodes 300 and/or second electrodes 400, the method of connection between the first electrode 300 and the second electrode 400, and the electrical resistance between the first electrode 300 and the second electrode 400.

Changes in the factors described above can alter the amount of electric current flowing between the first electrode 300 and second electrode 400, whereby the rate of the electrochemical reactions represented in Reaction Scheme 3 may be changed. A change in the rate of the electrochemical reactions will result in a change in the amount of hydrogen generated at the second electrode 400.

Thus, in embodiments of the invention, it is possible to adjust the amount of hydrogen generated by adjusting the amount of electric current flowing between the first electrode 300 and the second electrode 400. The underlying principle of this can be explained by the following Equation 1 using Faraday's law.

$${N}_{hydrogen} = \frac{i}{nE} \\ {N}_{hydrogen} = \frac{i}{2 \times 96485} ( mol ) \\ \begin{matrix}{V}_{hydrogen} = \frac{i}{2 \times 96485} \times 60 \times 22400 ( ml \text{/} min ) \\ = 7 \times i ( ml \text{/} min )\end{matrix} \qquad [ Equation 1 ]$$

Here, N_{hydrogen} represents the amount of hydrogen generated per second (mol/sec), and V_{hydrogen} represents the volume of hydrogen generated per minute (ml/min). i represents current (C/s), n represents the number of reacting electrons, and E represents the charge per one mole of electrons (C/mol).

With reference to Reaction Scheme 3 described above, as two electrons react at the second electrode 400, n equals 2, and the charge per one mole of electrons is about −96,485 coulombs.

The volume of hydrogen generated in one minute can be calculated by multiplying the amount of hydrogen generated in one second by the time (60 seconds) and the volume of one mole of hydrogen (22,400 ml).

If the fuel cell is used in a 2 W system, the required amount of hydrogen may be about 42 ml/mol, and 6 A of electric current may be needed. If the fuel cell is used in a 5 W system, the required amount of hydrogen may be about 105 ml/mol, and 15 A of electric current may be needed.

Accordingly, by adjusting the amount of electric current flowing between the first electrode 300 and the second electrode 400, the hydrogen generating apparatus 500 can be made to generate the amount of hydrogen required by the connected fuel cell.

Among the factors listed above that determine the reaction rate for generating hydrogen at the second electrode 400 of the hydrogen generating apparatus 500, those factors other than the electrical resistance between the first electrode 300 and the second electrode 400 are determined when constructing the hydrogen generating apparatus 500, and thus are not easy to change.

Also, for a greater electric current, the resistance has to be minimized not only in the control unit 502 but in all other elements. In the related art, however, clips may be used for connection between electrodes or between an electrode and the control unit, the contact resistance of which may result in a high resistance value of 300 to 500 mΩ.

An increase in contact resistance may cause a significant reduction in the electric current flowing between the first electrode and the second electrode, so that the actual flow rate of hydrogen generated per unit area of the electrode may not be very high. While it is possible to obtain the desired flow rate of hydrogen, even with high contact resistance, by increasing the size of the electrodes, this will result in a larger volume of the reactor, making it difficult to implement a small size for the hydrogen generating apparatus.

Also, the conventional connecting method of using clips results in unstable connections, so that the contact resistance may not remain constant, but may frequently change from values between 300 to 500 mΩ, whereby it may not be possible to obtain a constant flow rate.

In the hydrogen generating apparatus 500 according to embodiments of the invention, the resistance between electrodes may be reduced by depositing gold thin film layers, i.e. the first terminal layer 306 and second terminal layer 406, on portions of the first electrode 300 and second electrode 400 where the wire 310 may be soldered, whereby a desired flow rate of hydrogen may be obtained.

A low resistance meter was used to measure the resistance in a hydrogen generating apparatus 500 based on an embodiment of the invention, and a resistance value of less than 10 mΩ was observed.

Moreover, as the wire may be attached after forming the terminal layers on the electrodes by sputtering, the distance between the first electrode 300 and the second electrode 400 can be narrowed to 1 to 0.5 mm, so that the volume of the reactor can be reduced, and as there is less resistance for the movement of ions, the flow rate of hydrogen can be increased for the same amount of volume.

In addition, attaching the wire 310 by soldering can prevent changes in the degree of adhesion, so that the contact resistance need not be changed, and thus the changes in the amount of hydrogen generated can be decreased.

FIG. 11 is a graph representing the flow rate of hydrogen generated using conventional electrodes, where the wire is coupled to the electrodes using only clips.

FIG. 12 is a graph representing the flow rate of hydrogen generated in a hydrogen generating apparatus according to an embodiment of the invention, where gold thin film layers 306, 406 are sputtered onto the electrodes 300, 400, and the wire 310 is attached to the sputtered portions, to reduce contact resistance.

The tests in FIG. 11 and FIG. 12 were performed with a 2 mm distance between the first electrode 300 and second electrode 400, a potassium chloride (KCl) electrolyte having a concentration of 23%, for three first electrodes and three second electrodes placed in 60 cc of an aqueous electrolyte solution.

The results show that the maximum flow rate of hydrogen is 60 cc/min for FIG. 11, whereas the maximum flow rate is increased about twofold to 120 cc/min for FIG. 12.

As such, in embodiments of the present invention, the resistance may be reduced between the first electrode 300 and second electrode 400 to obtain a desired flow rate of hydrogen, and the volume of the reactor may be reduced by employing thin film deposition.

In embodiments of the invention, the first electrode 300 can be made of a metal other than magnesium that has a relatively high ionization tendency, such as iron (Fe) or an alkali metal such as aluminum (Al), zinc (Zn), etc. The second electrode 400 can be made of a metal such as platinum (Pt), copper (Cu), gold (Au), silver (Ag), iron (Fe), etc., that has a relatively lower ionization tendency than that of the metal used for the first electrode 300.

The control unit 502 may adjust the rate by which the electrons generated at the first electrode 300 by the electrochemical reactions are transferred to the second electrode 400, that is, the control unit 502 may adjust the electric current.

The control unit 502 may be inputted with the amount of power or amount of hydrogen required by the fuel cell, and if the required value is high, may increase the amount of electrons flowing from the first electrode 300 to the second electrode 400, or if the required value is low, may decrease the amount of electrons flowing from the first electrode 300 to the second electrode 400.

For example, the control unit 502 may include a variable resistance, to adjust the electric current flowing between the first electrode 300 and second electrode 400 by varying the resistance value, or may include an on/off switch, to adjust the electric current flowing between the first electrode 300 and second electrode 400 by controlling the on/off timing.

Of course, a fuel cell power generation system, which includes a fuel cell that receives the hydrogen supplied by the hydrogen generating apparatus 500 described above and converts the chemical energy of the hydrogen to electrical energy to produce a direct current, is encompassed within the scope of this invention.

As set forth above, in a method of connecting the electrodes of a hydrogen generating apparatus and the hydrogen generating apparatus using this method, according to aspects of the invention, the flow rate of hydrogen can be increased by reducing the contact resistance at the electrodes, and the volume of the hydrogen generating apparatus can be decreased by utilizing thin film deposition to minimize the distance between electrodes.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of connecting electrodes of a hydrogen generating apparatus, the method comprising:
depositing a first terminal layer onto one side of a first electrode, the first electrode configured to generate electrons;
attaching one side of a wire onto the first terminal layer;
depositing a second terminal layer onto one side of a second electrode, the second electrode configured to receive the electrons and generate hydrogen; and
attaching the other side of the wire onto the second terminal layer.

2. The method of claim 1, wherein depositing the first terminal layer is performed by a sputtering method.

3. The method of claim 1, wherein the first terminal layer contains any one of gold (Au) or platinum (Pt).

4. The method of claim 1, wherein the first terminal layer is deposited to a thickness of 10 to 10,000 nm.

5. The method of claim 1, further comprising, before depositing the first terminal layer:
stacking a mask on the first electrode, the mask having an aperture formed therein corresponding to the one side of the first electrode.

6. The method of claim 1, further comprising, before depositing the first terminal layer:
depositing a first attachment layer onto the one side of the first electrode.

7. The method of claim 6, wherein the first attachment layer contains at least one selected from a group consisting of titanium (Ti), chromium (Cr), nickel (Ni), and aluminum (Al).

8. The method of claim 6, wherein the first attachment layer is deposited to a thickness of 1 to 1,000 nm.

9. The method of claim 1, further comprising, before depositing the second terminal layer:
stacking a mask on the second electrode, the mask having an aperture formed therein corresponding to the one side of the second electrode.

10. The method of claim 1, further comprising, before depositing the second terminal layer:
depositing a second attachment layer onto the one side of the second electrode.

11. The method of claim 1, wherein attaching the wire is performed by a soldering method.

12. A hydrogen generating apparatus comprising:
an electrolyte bath holding an aqueous electrolyte solution;
a first electrode held inside the electrolyte bath, configured to generate electrons, and having a first terminal layer formed on one side;
a second electrode held inside the electrolyte bath with a particular distance to the first electrode, configured to generate hydrogen using the electrons and the aqueous electrolyte solution, and having a second terminal layer formed on one side; and
a wire having one side soldered to the first terminal layer and the other side soldered to the second terminal layer to allow a movement of the electrons.

13. The hydrogen generating apparatus of claim 12, further comprising:
a first attachment layer interposed between the first terminal layer and the first electrode.

14. The hydrogen generating apparatus of claim 12, further comprising:
a second attachment layer interposed between the second terminal layer and the second electrode.

15. The hydrogen generating apparatus of claim 12, wherein the first terminal layer contains any one of gold (Au) or platinum (Pt).

16. The hydrogen generating apparatus of claim 12, wherein a thickness of the first terminal layer is 10 to 10,000 nm.

17. The hydrogen generating apparatus of claim 13, wherein the first attachment layer contains at least one selected from a group consisting of titanium (Ti), chromium (Cr), nickel (Ni), and aluminum (Al).

18. The hydrogen generating apparatus of claim 13, wherein a thickness of the first attachment layer is 1 to 1,000 nm.
